(19) United States
(12) Patent Application Publication
(10) Pub. No.: US 2024/0086769 A1
(43) Pub. Date: Mar. 14, 2024

(54) COMPUTER-IMPLEMENTED METHOD AND DEVICE FOR DETERMINING A PREDICTION FOR A VARIABLE OF A TECHNICAL SYSTEM, USING A MACHINE LEARNING MODEL

(71) Applicant: Robert Bosch GmbH, Stuttgart (DE)

(72) Inventors: Matthias Bitzer, Stuttgart (DE); Christoph Zimmer, Korntal (DE); Mona Meister, Renningen (DE)

(21) Appl. No.: 18/453,779

(22) Filed: Aug. 22, 2023

(30) Foreign Application Priority Data
Sep. 6, 2022 (DE) 10 2022 209 254.6

(51) Int. Cl. G06N 20/00

(52) U.S. Cl. CPC G06N 20/00

(57) ABSTRACT

A device and a computer-implemented method for determining a variable of a technical system, using a machine learning model. A kernel for the model is selected from a set of kernels as a function of a selection criterion, and a first data set which includes mutually assigned input variables and output variables of the technical system. The selection criterion is determined for a kernel that is selected from the set of kernels as a function of an acquisition function, the acquisition function being determined as a function of a second data set that includes pairs of kernels from the set of kernels and a selection criterion. The pairs of kernels are determined over respectively one pair of kernels from the set of kernels and as a function of the second data set. Representations of a first and second kernel are provided.

### CROSS REFERENCE

The present application claims the benefit under 35 U.S.C. § 119 of German Patent Application No. DE 10 2022 209 254.6 filed on Sep. 6, 2022, which is expressly incorporated herein by reference in its entirety.

### BACKGROUND INFORMATION

The present invention relates to a computer-implemented method and a device for determining a prediction for a variable of a technical system, using a machine learning model.

G. Malkomes, C. Schaff, and R. Garnett, “Bayesian optimization for automated model selection,” in D. Lee, M. Sugiyama, U. Luxburg, I. Guyon, and R. Garnett, editors, Advances in Neural Information Processing Systems, volume 29, Curran Associates, Inc., 2016, provide an option for determining a machine learning model.

### SUMMARY

By use of features of the computer-implemented method and the device according to the present invention, a procedure that is improved in particular with regard to consumption of computing resources is provided.

According to an example embodiment of the present invention, the computer-implemented method for determining a prediction for a variable of a technical system, using a machine learning model, provides that a kernel for the model is selected from a set of kernels as a function of a selection criterion and a first data set, the first data set including mutually assigned input variables and output variables of the technical system, the selection criterion being determined for a kernel from the set of kernels that is selected from the set of kernels as a function of an acquisition function, the acquisition function being determined as a function of a second data set that includes pairs of kernels from the set of kernels and a selection criterion, the pairs of kernels, as a function of a kernel, being determined over respectively one pair of kernels from the set of kernels and as a function of the second data set, a representation of a first kernel and a representation of a second kernel from the set of kernels being provided, the representation of the first kernel including at least one symbol that characterizes a kernel, the representation of the second kernel including at least one symbol that characterizes a kernel, a distance between the first kernel and the second kernel being determined as a function of a difference between a number of symbols that characterize a predefined kernel in the representation of the first kernel, and a number of symbols that characterize the predefined kernel in the representation of the second kernel, or as a function of a difference between in particular relative frequencies of these symbols, the kernel being determined over the pair of kernels for determining the kernel for the model as a function of the distance, and the prediction for the variable, in particular a position, a speed, or an acceleration, being determined using the model. The kernel of the model, i.e., the covariance of the model, is determined over kernels as a function of a kernel, i.e., a kernel that is determined as a function of kernels, i.e., covariances of underlying statistical hypotheses. The first kernel represents a first statistical hypothesis concerning the technical system for the model. The second kernel represents a second statistical hypothesis concerning the technical system for the model. The predefined kernel represents a base kernel, which may include the first kernel or the second kernel. The number or the relative frequency of the symbols indicates a frequency with which the same base kernel is used. The frequency represents a condensed statistical representation of the particular kernel. Instead of directly determining the difference between the two kernels, a distance between the two kernels is determined using the condensed statistical representation. This involves significantly less computing time, and allows a computation using considerably fewer computing resources than determining the difference of the Gaussian processes, associated with the kernels, in the functional space. This speeds up each iteration in a search with the aid of Bayesian optimization over the kernels from the set of kernels, so that an optimal kernel for the given data set of the technical system may be found more quickly.

According to an example embodiment of the present invention, it may be provided that the representation of the first kernel includes at least one symbol that characterizes an operator via which two kernels are combinable, the representation of the first kernel including at least one sequence of symbols that characterizes an application of at least one operator to a kernel, the representation of the second kernel including at least one symbol that characterizes an operator via which two kernels are combinable, the representation of the second kernel including at least one sequence of symbols that characterizes an application of at least one operator to a kernel, the distance being determined as a function of a difference between a number of sequences in the first representation that include a symbol for the predefined kernel, and a number of sequences in the second representation that include a symbol for the predefined kernel, or as a function of a difference between in particular relative frequencies of these sequences. The kernel of the model is determined, for example, as a function of composite kernels. The operator defines the way in which a kernel in the combination is taken into account. The sequence of the symbols indicates an order in which the operators are applied to a kernel. The number or relative frequency of the sequences indicates a frequency with which the same operators are applied in the same order to the same base kernel. Taking this frequency into account additionally enhances the model.

According to an example embodiment of the present invention, it may be provided that the representation of the first kernel includes at least one symbol that characterizes an operator via which two kernels are combinable, the representation of the first kernel including at least one sequence of symbols that characterizes an application of at least one operator to at least two kernels, the representation of the second kernel including at least one symbol that characterizes an operator via which two kernels are combinable, the representation of the second kernel including at least one sequence of symbols that characterizes an application of at least one operator to at least two kernels, the distance being determined as a function of a difference between a number of sequences in the first representation that include a symbol for the predefined kernel and at least one further kernel, and a number of sequences in the second representation that include a symbol for the predefined kernel and at least one further kernel, or as a function of a difference between in particular relative frequencies of these sequences. The sequence defines the order of kernels and operators in the combination. The number or relative frequency of sequences indicates a frequency with which the same operator or the same operators is/are applied to the same kernels. Taking this frequency into account additionally enhances the model.

According to an example embodiment of the present invention, a weight is preferably determined for at least one of the differences, the distance being determined as a function of a sum in which the at least one difference is weighted with the weight. A weighted consideration of the frequencies additionally enhances the model.

The weight is preferably determined in a training of the model on at least one of the data sets. This means that the weights are also learned in the training. This additionally enhances the model.

According to an example embodiment of the present invention, it may be provided that the first kernel includes parameters, values for the parameters that meet a predefined criterion being determined as a function of at least one of the data sets. In the training, the kernel is thus trained on the data set.

In one example, the prediction for the variable is output. This means that the prediction for the variable of the technical system is determined using the model and is output. The model represents, for example, a virtual sensor for the variable.

In one example, an input variable of the model is received or detected, the prediction for the variable being determined as a function of the input variable, using the model. This means that the input variable influences the variable of the technical system that is determined using the model. The input variable represents, for example, a measurable or measured operating variable of the system or of its environment.

According to an example embodiment of the present invention, a device for determining a prediction for a variable of a technical system, using a machine learning model, includes at least one processor and at least one memory, the memory being designed to store instructions, the method running when the instructions are executed, the processor being designed to execute the instructions. This device has advantages that correspond to those of the method.

In one example, the device includes an interface that is designed to output the prediction for the variable.

In one example, the device includes an interface that is designed to receive or detect an input variable for the model.

According to an example embodiment of the present invention, a computer program that includes instructions that are executable by a computer, the method running when the instructions are executed by the computer, has advantages that correspond to those of the method.

Further advantageous specific embodiments of the present invention are apparent from the following description and the figures.

### BRIEF DESCRIPTION OF THE DRAWINGS

FIG. 1 shows a schematic illustration of a device for determining a prediction for a variable of a technical system, using a machine learning model, according to an example embodiment of the present invention.

FIG. 2 shows steps in a method for determining the prediction for the variable, using the model, according to an example embodiment of the present invention.

FIG. 3 shows a tree as a representation of an example of a composite first kernel for the model, according to the present invention.

FIG. 4 shows a tree as a representation of an example of a composite second kernel for the model, according to the present invention.

### DETAILED DESCRIPTION OF EXAMPLE EMBODIMENTS

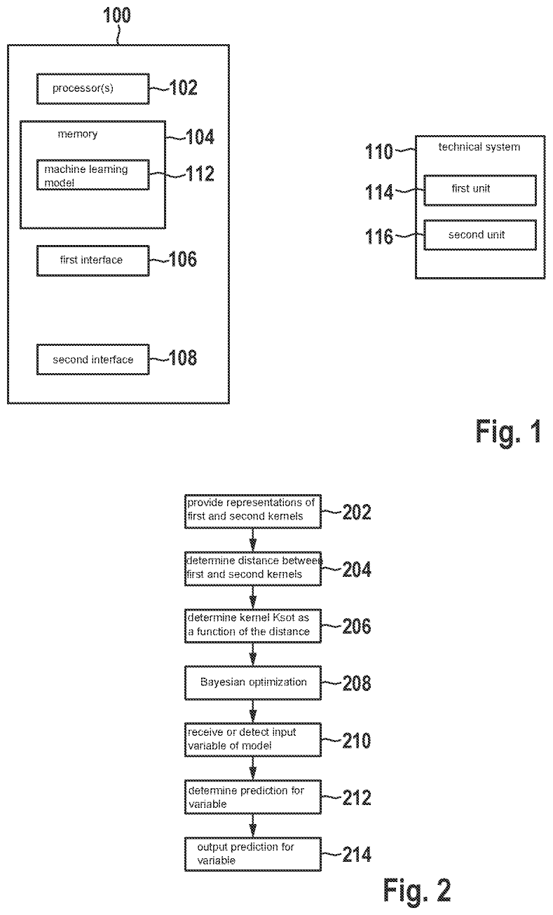

A device 100 is schematically illustrated in FIG. 1. Device 100 includes at least one processor 102 and at least one memory 104.

Device 100 includes a first interface 106 and a second interface 108.

A technical system 110 is schematically illustrated in FIG. 1.

Technical system 110 is a physical system, for example. Technical system 110 is a computer-controlled machine, for example, a robot, for example, in particular a vehicle, a production machine, a household appliance, a tool, a personal assistance system, or an access control system.

Device 100 is designed to determine a prediction yᵢ for a variable y of technical system 110, using a machine learning model 112.

Variable y includes a physical variable, for example a position, a speed, or an acceleration of technical system 110 or of a portion of technical system 100.

In the example, the at least one memory 104 includes model 112.

In the example, the at least one memory 104 is designed to store instructions, and a computer-implemented method, described below, runs when the instructions are executed.

The at least one processor 102 is designed to execute the instructions.

In one example, first interface 106 is designed to output prediction yᵢ for variable y.

In one example, second interface 108 is designed to receive or detect an input variable X for model 112. In one example, input variable X includes a physical variable, for example a position, a speed, or an acceleration of technical system 110 or of a portion of technical system 100.

In the example, technical system 110 optionally includes a first unit 114 for receiving prediction yᵢ for variable y from first interface 106.

First unit 114 is preferably designed to activate technical system 110 as a function of prediction yᵢ for variable y, for example to influence the position, the speed, or the acceleration of technical system 110 or of a portion thereof.

In the example, technical system 110 optionally includes a second unit 116 for sending input variable X to second interface 108.

Second unit 116 is preferably designed to detect input variable X at technical system 110.

Stated as an example of the instructions are instructions that are executable on a computer, the method running when the instructions are executed by the computer. In one example, a computer program includes the instructions.

Device 100 is designed to adapt model 112 to a predefined data set D.

Model 112 includes a Gaussian process GP(μ(·), k*( [symbol] )) that includes a kernel k*( [symbol] ). Kernel k*( [symbol] ) is determined over Gaussian processes GP(μ(·), k*( [symbol] )) using a Gaussian process GP(μ_{c}(·), K_{SOT}( [symbol] )), reference symbol μ_{c}(·) denoting an average value function and reference symbol K_{SOT}( [symbol] ) denoting a kernel. Kernel K_{SOT}( [symbol] ) includes a plurality of kernels k. In the example, kernel k*( [symbol] ) is determined by Bayesian optimization as a function of kernel K_{SOT}( [symbol] ).

A Gaussian process GP is a distribution over functions f: X→ [symbol] over a predefined input space X. The distribution is completely defined by a covariance function, i.e., a kernel K(x,x′)=Cov(f(x),f(x′)), and an average value function μ(x):E[f(x)], where E is the expected value. The Gaussian process is referred to below as f˜GP(μ(·), k( [symbol] )) for short.

In the example, the Gaussian processes are centered; i.e., μ_{c}(·)=constant, for example 0, and μ(·)=0.

A kernel k is a function k:X×X→ [symbol] . Kernel K generates the main properties of a sample, for example smoothness, periodicity, or extensive correlation. Kernel k may be interpreted as a similarity measure between two elements of input space X, kernel k of Gaussian process GP being assigned to values of the function whose input variables X according to kernel k are more similar to one another than other values in kernel k, which are higher values than the other values.

Gaussian process GP is not limited to a Euclidian input space X⊂ [symbol] ^{d} of a dimension d, but, rather, may also be defined on a structured space such as a tree or a graph. In the example, the Gaussian process over Gaussian processes is defined on the structured space.

In the example, a prediction yᵢ for variable y is determined using Gaussian process GP(μ(·), k*( [symbol] )). For prediction a data set D=(X, y) is predefined that includes input variable X and variable y, it being assumed that f˜GP(μ(·), k*( [symbol] )) and that prediction yᵢ is determined as a function of a disturbance variable ϵᵢ: yᵢ=f(xᵢ)+ϵᵢ, disturbance variable E i being independently extracted, with a uniform distribution, from a distribution N(0, σ²) having variance a σ²: ϵᵢ˜N(0, σ²).

Data set D is measured at technical system 110, for example.

Device 100 is designed to determine, using data set D, a Gaussian process including an average value function μ_{D}(x) and a covariance function, i.e., a kernel k_{D}(x, y):

μ_{D}(x)=μ(x)+μ(x)+k(x)^{T}(K+σ²I)⁻¹(x−μ(X))

k_{D}(x, y)=k(x, y)−k(x)^{T}(K+σ²I)⁻¹(k(y))

where K=[k(xₘ, xₗ)]_{m,l=1}^{N} and k(x)=[k(x, x₁], . . . , k(x, x_{N})]^{T}, and I is the unit matrix having an appropriate dimension. This Gaussian process models an a posteriori distribution p(f|D) over function f.

In the example, a prediction of a likelihood p(f*|x*,D) is determined using a distribution p(f*|x*,D)=N(μ_{D}(x*), k_{D}(x*, x*)).

Device 100 is designed to determine, using data set D, values for parameters θ via which kernel k_{D} is defined. In one example, the values of parameters θ are determined by maximizing a marginal likelihood p(y|X, θ, σ²)=N(x; μ(X), k_{θ}(X, X)+σ²I, where I is the unit matrix having an appropriate dimension.

In one example, an a priori likelihood p(θ) is predefined for parameters θ, the values of parameters θ being determined by estimating a maximum a posteriori likelihood p(θ|D).

In the example, a structural form of kernel k_{D} is determined using data set D. The structural form determines a statistical hypothesis, from which it is assumed that the structural form applies for the process of the prediction.

Device 100 is designed to make a selection in a discrete space of kernels K:={k₁, k₂, . . . }. It may be provided that the space is infinite.

Device 100 is designed to solve the following optimization problem as a function of a selection criterion g(k_{D}|D):K→

[symbol]

$${k}^{*} = {argmax}_{{k}_{D} ∈ K} g ( {k}_{D} \vert D )$$

where reference symbol k* denotes the kernel of model 112 that solves the optimization problem. In the example, device 100 is designed to solve the optimization problem based on evidence. In the example, selection criterion g(k_{D}|D) is logarithmic evidence of a marginalized Gaussian process

g(k_{D}|D)=log p(y|X, k_{D})=log ∫p(y|X, θ, σ², k_{D})p(σ²)p(θ|k_{D})dθdσ²

proceeding from a predefined a priori likelihood p(θ) for parameters θ of kernel k_{D}, where p(σ²) is a variance of the likelihood and p(y|X, k) is evidence for model 112. In one example, selection criterion g(k_{D}|D) is determined as a function of p(θ, σ²|D) , using a Laplace approximation.

In the space of kernels K, for a first kernel kᵢ(x, x′) and a second kernel kⱼ(x, x′) a composite kernel is defined by a first expression kᵢ(x, x′)+kⱼ(x, x′). In the space of kernels K, for first kernel kᵢ(x, x′) and second kernel kⱼ(x, x′) a composite kernel is defined by a second expression kᵢ(x, x′)×kⱼ(x, x′). First kernel kᵢ(x, x′) is a base kernel. First kernel kᵢ(x, x′) is represented by a first symbol Bᵢ. Second kernel kᵢ(x, x′) is a base kernel. Second kernel kᵢ(x, x′) is represented by a second symbol Bⱼ. First expression kᵢ(x, x′)+kⱼ(x, x′) is an example of a composite kernel. Second expression kᵢ(x, x′)×kⱼ(x, x′) is an example of a composite kernel.

The space of kernels K represents a search space. Base kernels and composite kernels are findable in the space of kernels K. A composite kernel includes at least two base kernels to which at least one operator is applied. A base kernel is represented by a symbol B. An expression that defines a composite kernel is represented by a symbol S.

For a base kernel B and an expression S, composite kernels are achievable via the following operations:

S→S+B

S→S×B

B→B′

where an operator + denotes an addition of a base kernel to an expression, an operator × denotes a multiplication of an expression by a base kernel, and an operation → denotes an exchange of a base kernel with another base kernel.

In the example, a set of τ symbols is used for base kernels {B₁, . . . , B_{τ}} and a set of l symbols is used for operators {T₁, . . . , Tₗ}, where Tᵢ: Ξ×Ξ→Ξ represent symbols for operators on a space of possible kernel functions Ξ.

In the example, it is provided to determine an expression, an operator being applied to an expression and to a base kernel: S→Tᵢ(S,B). The operator is represented by a symbol Tᵢ.

In the example, it is provided to exchange a base kernel with another base kernel: B→B′.

Device 100 is designed to solve the optimization problem with the aid of a symbolic description, using the symbols. A resulting search space \tilde{K}:=L_{M} of a search depth M is defined by a set of T base kernels {k₁, . . . , k_{τ}} that are symbolically represented by τ symbols {B₁, . . . , B_{τ}}, and a set of symbols for operators Tᵢ: Ξ×Ξ→Ξ, where

L₀:={k₁, . . . , k_{τ}}

Lᵢ:={Tⱼ(k₁, k₂)ϵΞ|k₁, k₂ϵLᵢ₋₁, j=1, . . . , l}ULᵢ₋₁, for i=1, . . . , M.

Kernels k ∈ \tilde{K} are findable in search space \tilde{K}. It may be provided that a composite kernel k is found using different expressions.

In the example, it is provided that a tree Tᵢ represents a composite kernel. In the example, for trees Tᵢ a mapping f:\tilde{K}→{T₁, T₂, . . . } is provided that maps a kernel kᵢ ∈ \tilde{K}, which is more findable in search space \tilde{K}, onto a tree Tᵢ that represents this kernel For example, device 100 is designed to implement this mapping via filter operations which replace ambiguous mappings with an unambiguous mapping.

Device 100 is designed to solve the optimization problem in iterations by use of a Bayesian optimization.

Device 100 is designed to provide values θ₀ for parameters θ for a first of iterations t=0. Device 100 is designed to provide a data set D₀ for the first of the iterations.

Device 100 is designed to determine a data set Dₜ for each iteration t as a function of data set D₀.

Device 100 is designed to adapt Gaussian process GP(μ_{c}(·), K_{SOT}( [symbol] )) over Gaussian processes GP(μ(·), k( [symbol] )) in iterations t at a particular data set Dₜ.

Device 100 is designed to determine, as a function of kernel K_{SOT} and particular data set Dₜ, next kernel kₜ for which selection criterion g(kₜ|D) is determined.

Device 100 is optionally designed to carry out an optimization of an acquisition function a(k|Dₜ) in the Bayesian optimization with the aid of an evolutionary algorithm.

Device 100 is designed to determine kernel k*.

In the example, a search space that includes a set of kernels {k1, k2, . . . } is provided. In the example, kernel k* is determined by a search over the search space, selection criterion g(k_{D}|D) via which kernel k* is determined being a function of data set D. Data set D includes input variables X and output variables y.

A Bayesian optimization is used for the search. Gaussian process GP(μ_{c}(·), K_{SOT}( [symbol] )) is used for the Bayesian optimization. In the example, kernel K_{SOT} of the Gaussian process is used. Kernel K_{SOT} is defined on the search space; i.e., kernel K_{SOT} is a function on the search space.

Kernel K_{SOT} is a function that includes each of two kernels as an argument. Kernel K_{SOT}(k₁, k₂) is determined, for example, for two kernels k₁, k₂ in which the tree representation of the two kernels k₁, k₂ is compared, and a distance between them is computed. This distance of the tree representation may be quickly computed, and contains enough information to generate a meaningful distance.

Kernel K_{SOT} has a decisive influence on the Bayesian optimization search, and thus quickly results in a kernel k* that maximizes selection criterion g(k_{D}|D).

Kernel K_{SOT} speeds up the search for the following reasons:
Kernel K_{SOT} defines the Gaussian process in the Bayesian optimization. This Gaussian process is a better model for the target function, i.e., selection criterion g(k|D), so that the Bayesian optimization does not have to sample as many kernels in order to find a good one.
For each iteration, the Bayesian optimization itself also requires a certain computing time, which is speeded up due to the fact that only the trees are used to compute kernel K_{SOT}.

This means that a determination of kernel k* includes a determination of the values for parameters θ that meet a predefined criterion. In the example, it is provided as a criterion that the values for parameters θ solve the optimization problem.

Device 100 is designed, in particular as part of the Bayesian optimization, to add kernel k* and selection criterion g(k_{D}|D) from iteration t to data set Dₜ₊₁ for next iteration t+1. This means that Dₜ₊₁=DₜU{(k_{D}, g(k_{D}|D)}.

FIG. 2 schematically illustrates steps in the computer- implemented method for determining the variable of technical system 110, using a machine learning model 112.

For a training of model 112, steps of the method are carried out in iterations for various kernels. Kernel k* for model 112 is determined in the training.

In the training, data set Dₜ is predefined, for example, for each iteration t, values for parameters θ being determined that meet the predefined criterion. In the iterations, a distance between two kernels is determined for a plurality of pairs of a first kernel kᵢ and a second kernel kⱼ as a function of a difference between their respective symbolic representations. Kernel K_{SOT} is determined for determining kernel k* of model 112 as a function of differences of distributions over symbolic representations, which are determined for the plurality of pairs of kernels.

The method includes a step 202.

A representation of first kernel kᵢ and a representation of second kernel kⱼ are provided in step 202.

The representation of first kernel kᵢ includes at least one symbol that characterizes a kernel.

The representation of second kernel kⱼ includes at least one symbol that characterizes a kernel.

A kernel that is represented by a symbol depicts a base kernel.

In the example, for the following kernels the following symbols are provided:

linear kernel: LIN

periodic kernel: PER

squared exponential kernel: SE

For other base kernels, other symbols may be provided.

The representation of first kernel kᵢ includes at least one base kernel. For example, first kernel kᵢ is a kernel that is combined from multiple base kernels. A representation of second kernel kⱼ includes at least one base kernel. For example, second kernel kⱼ is a kernel that is combined from multiple base kernels.

One example of a composite first kernel is

kᵢ=LIN+((PER×SE)+SE)

where + and × are operators, and are each assigned to a symbol as follows:

+: ADD

×: MULT

Other operators may also be provided. A sequence in which the operators are applied to the kernels is defined in the mathematical expression by the mathematical ranking of the operators or by a priority computation of a subsection of the expression, and in particular is defined by parentheses ( ).

One example of a composite second kernel is

kⱼ=LIN+SE+((PER×LIN)+SE)

The representation of a composite kernel may also be depicted as a tree in which a root node includes an operand from the expression and in which the base kernels from the expression are depicted as a leaf.

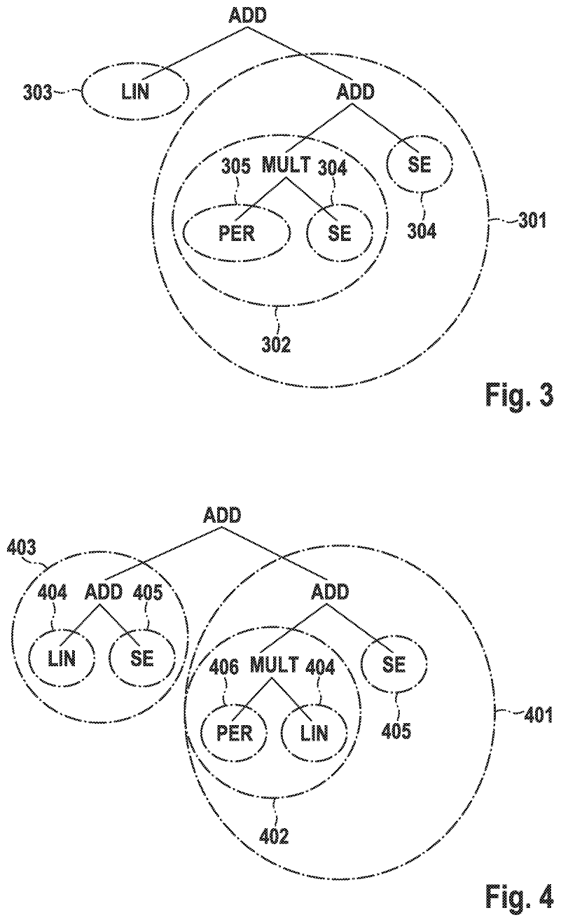

FIG. 3 illustrates a first tree Tᵢ as a representation of the example of a composite first kernel

FIG. 4 illustrates a second tree Tⱼ as a representation of the example of a composite second kernel kⱼ.

The method includes a step 204.

A distance between first kernel kᵢ and second kernel kⱼ is determined in step 204. The distance is determined from the respective representation of the kernels. This is considerably less CPU-intensive than determining the distance between the kernels as a function of distributions of the kernels in a functional space.

In the example, in the representation of a kernel as a function of a predefined kernel, a number of symbols that represent the same base kernel in the representation is determined. The predefined kernel is a base kernel. In the example, a particular number for each of base kernels LIN, SE, or PER is determined. This means that in the example, the predefined kernel is LIN, SE, or PER.

In a first example, in each case a first number of symbols is determined which in the representation of first kernel kᵢ characterize the particular predefined kernel.

For the example of first kernel kᵢ, the following first numbers for base kernels LIN, SE, and PER are determined from first tree Tᵢ, for example:

LIN: 1

SE: 2

PER: 1

In the first example, in each case a second number of symbols is determined that characterize the kernel predefined in each case in the representation of second kernel kⱼ.

For the example of second kernel kⱼ, the following second numbers for base kernels LIN, SE, and PER are determined from second tree Tⱼ, for example:

LIN: 2

SE: 2

PER: 1

A first difference is determined in the first example. The first difference is a difference between the first relative frequency of symbols and the second relative frequency of symbols.

In the example, the first relative frequencies for the various predefined kernels, i.e., the particular base kernels, are combined in a vector.

For the example of first kernel kᵢ, the elements of first vector ω_{i,b} are defined as follows, based on the frequency of occurrence of individual base kernels LIN, SE, PER, in that order:

$${ω}_{i . b} = {( \frac{1}{4} , \frac{1}{2} , \frac{1}{4} )}^{T}$$

For the example of second kernel kⱼ, the elements of first vector ω_{i,b} are defined as follows, based on the frequency of occurrence of individual base kernels LIN, SE, PER, in that order:

$${ω}_{j , b} = {( \frac{2}{5} , \frac{2}{5} , \frac{1}{5} )}^{T}$$

In the example, the first difference is determined for each base kernel, i.e.,

$$\frac{1}{4} - \frac{2}{5}$$

$$\frac{1}{2} - \frac{2}{5}$$

$$\frac{1}{4} - \frac{2}{5}$$

In one example, the distance is determined, using these vectors, by a sum of the absolute values of the element-wise differences:

$$\vert \frac{1}{4} - \frac{2}{5} \vert + \vert \frac{1}{2} - \frac{2}{5} \vert + \vert \frac{1}{4} - \frac{1}{5} \vert = \frac{3}{10}$$

This means that for kernels that are based on multiple different base kernels, the distance is determined as a function of the first differences. For kernels that are based on a base kernel that is used multiple times, the distance is determined as a function of the first difference for this base kernel.

In a second example, the representation of first kernel kᵢ, first tree Tᵢ, for example, includes at least one symbol that characterizes an operator via which two kernels are combinable.

In the example of first kernel kᵢ these are symbols ADD and MULT.

In the second example, the representation of first kernel kᵢ, first tree Tᵢ, for example, includes at least one sequence of symbols that characterizes an application of at least one operator to a kernel.

In the example of first kernel kᵢ, these are the sequences:

ADD, ADD, MULT, PER: 1

ADD, ADD, MULT, SE: 1

ADD, ADD, SE: 1

ADD, LIN: 1

A sequence represents a path from the root node to a leaf. For a base kernel, the number indicates how many paths exist from the root node, having the same order of operands, that lead to a leaf that represents the predefined base kernel.

In the second example, the representation of second kernel kⱼ, second tree Tⱼ, for example, includes at least one symbol that characterizes an operator via which two kernels are combinable.

In the second example, the representation of second kernel kⱼ, second tree Tⱼ, for example, includes at least one sequence of symbols that characterizes an application of at least one operator to a kernel.

In the example of second kernel kⱼ, these are the sequences:

ADD, ADD, MULT, PER: 1

ADD, ADD, MULT, LIN: 1

ADD, ADD, SE: 2

ADD, ADD, LIN: 1

In the second example, in each case a first number of sequences in the first representation, in first tree Tᵢ, for example, that include a symbol for the particular predefined kernel is determined.

In the second example, in each case a second number of sequences in the second representation Tⱼ that include a symbol for the particular predefined kernel is determined.

For example, the numbers are determined in the particular tree.

A second difference is determined in the second example. The second difference is a difference between the first relative frequency of sequences and the second relative frequency of sequences.

In the second example, the distance is determined as a function of the first and the second difference.

In one example, the distance is determined as a function of a sum of these differences.

In the example, the relative frequencies for the various sequences are combined in a vector.

For the example of first kernel kᵢ, the elements of a first vector ω_{i,p} are defined as follows, based on the frequency of occurrence of the individual sequences, in the above-stated order:

$${ω}_{i , p} = {( \frac{1}{4} , \frac{1}{4} , \frac{1}{4} , \frac{1}{4} , 0 , 0 )}^{T}$$

For the example of second kernel kⱼ, the elements of first vector ω_{j,p} are defined as follows, based on the frequency of occurrence of the individual sequences, in the above-stated order:

$${ω}_{j , p} = {( \frac{1}{5} , 0 , \frac{2}{5} , 0 , \frac{1}{5} , \frac{1}{5} )}^{T}$$

In the example, the first difference is determined for each sequence, i.e.,

$$\frac{1}{4} - \frac{1}{5}$$

$$\frac{1}{4} - 0$$

$$\frac{1}{4} - \frac{2}{5}$$

$$\frac{1}{4} - 0$$

$$0 - \frac{1}{5}$$

$$0 - \frac{1}{5}$$

In one example, the distance is determined, using these vectors, by a sum of the absolute values of the element-wise differences:

$$\vert \frac{1}{4} - \frac{1}{5} \vert + \vert \frac{1}{4} - 0 \vert + \vert \frac{1}{4} - \frac{2}{5} \vert + \vert \frac{1}{4} - 0 \vert + \vert 0 - \frac{1}{5} \vert + \vert 0 - \frac{1}{5} \vert = \frac{11}{10}$$

This means that for kernels that are based on multiple different sequences, the distance is determined as a function of the second differences. For kernels that are based on a sequence that is used multiple times, the distance is determined as a function of the second difference for this sequence.

In a third example, the representation of first kernel kᵢ, first tree Tᵢ, for example, includes at least one symbol that characterizes an operator via which two kernels are combinable.

In the third example, the representation of first kernel kᵢ, first tree Tᵢ, for example, includes at least one sequence of symbols that characterizes an application of at least one operator to at least two kernels.

In the example of a first tree Tᵢ, this sequence of symbols is characterized by subtrees that include at least one operator and at least two leaves, or one leaf each. First tree Tᵢ includes a first subtree 301 that represents the following subexpression:

(PER×SE)+SE

First tree Tᵢ includes a second subtree 302 that represents the following subexpression:

PER×SE

First tree Tᵢ includes a third subtree 303 that represents the following subexpression:

LIN

First tree Tᵢ includes two fourth subtrees 304, each of which represents the following subexpression:

SE

First tree Tᵢ includes a fifth subtree 305 that represents the following subexpression:

PER

In the third example, the representation of second kernel kⱼ, second tree Tⱼ, for example, includes at least one symbol that characterizes an operator via which two kernels are combinable.

In the third example, the representation of second kernel kⱼ, second tree Tⱼ, for example, includes at least one sequence of symbols that characterizes an application of at least one operator to at least two kernels.

In the example of a second tree Tⱼ, this sequence of symbols is characterized by subtrees that include at least one operator and at least two leaves, or one leaf each. Second tree Tⱼ includes a first subtree 401 that represents the following subexpression:

(PER×LIN)+SE

Second tree Tⱼ includes a second subtree 402 that represents the following subexpression:

PER×LIN

Second tree Tⱼ includes a third subtree 403 that represents the following subexpression:

LIN+SE

Second tree Tⱼ includes two fourth subtrees 404, each of which represents the following subexpression:

LIN

Second tree Tⱼ includes two fifth subtrees 405 that represent the following subexpression:

SE
Second tree Tⱼ includes a sixth subtree 406 that represents the following subexpression:

PER

In the third example, a third number of sequences in the first representation, in first tree Tᵢ, for example, that include a symbol for the predefined kernel and at least one further kernel is determined.

In the third example, a fourth number of sequences in the second representation, in second tree Tⱼ, for example, that include a symbol for the predefined kernel and at least one further kernel is determined.

A third difference is determined in the third example. The third difference is, for example, a difference between the third relative frequency of sequences and the fourth relative frequency of sequences.

In the example, the relative frequencies for the various sequences are combined in a vector.

For the example of first kernel kᵢ, the elements of a first vector ω_{i,s} are defined as follows, based on the frequency of occurrence of the individual subtrees, in the above-stated order:

$${ω}_{i , s} = {( \frac{1}{7} , \frac{1}{7} , \frac{1}{7} , \frac{1}{7} , \frac{2}{7} , \frac{1}{7} , 0 , 0 , 0 , 0 )}^{T}$$

For the example of second kernel kⱼ, the elements of first vector ω_{j,s} are defined as follows, based on the frequency of occurrence of the individual subtrees, in the above-stated order:

$${ω}_{j , p} = {( 0 , 0 , 0 , \frac{2}{9} , \frac{2}{9} , \frac{1}{9} , \frac{1}{9} , \frac{1}{9} , \frac{1}{9} , \frac{1}{9} )}^{T}$$

In the example, the first difference is determined for each sequence, i.e.,

$$\frac{1}{7} - 0$$

$$\frac{1}{7} - 0$$

$$\frac{1}{7} - 0$$

$$\frac{1}{7} - \frac{2}{9}$$

$$\frac{2}{7} - \frac{2}{9}$$

$$\frac{1}{7} - \frac{1}{9}$$

$$0 - \frac{1}{9}$$

$$0 - \frac{1}{9}$$

$$0 - \frac{1}{9}$$

$$0 - \frac{1}{9}$$

In one example, the distance is determined, using these vectors, by a sum of the absolute values of the element-wise differences:

$$\vert \frac{1}{7} - 0 \vert + \vert \frac{1}{7} - 0 \vert + \vert \frac{1}{7} - 0 \vert + \vert \frac{1}{7} - \frac{2}{9} \vert + \vert \frac{2}{7} - \frac{2}{9} \vert + \vert \frac{1}{7} - \frac{1}{9} \vert + \vert 0 - \frac{1}{9} \vert + \vert 0 - \frac{1}{9} \vert + \vert 0 - \frac{1}{9} \vert + \vert 0 - \frac{1}{9} \vert = \frac{22}{21}$$

This means that for kernels that are based on multiple different base kernels, the distance is determined as a function of the third differences. For kernels that are based on a subtree that is used multiple times, the distance is determined as a function of the third difference for this base subtree.

In the third example, the distance is determined as a function of the first and the third difference, or as a function of the first, the second, and the third difference.

In one example, the distance is determined as a function of a sum of these differences.

It may be provided that a weight is determined for at least one of the differences. For the first difference, for example a first weight α₁ is determined. For the second difference, for example a second weight α₂ is determined. For the third difference, for example a third weight α₃ is determined.

In one example, the distance is determined as a function of a sum in which at least one difference is weighted with the weight that is assigned to this difference.

For the example of first kernel kᵢ and for the example of second kernel kⱼ, for example the following weighted distance is determined:

$$d ( {k}_{i} , {k}_{j} ) = {α}_{1} \frac{3}{10} + {α}_{2} \frac{11}{10} + {α}_{3} \frac{22}{21}$$

The method includes a step 206.

A kernel K_{SOT} is determined in step 206 as a function of the distance.

In the example, kernel K_{SOT} is determined as follows:

$${K}_{SOT} ( {k}_{i} , {k}_{j} ) = {σ}^{2} exp ( - \frac{d ( {k}_{i} , {k}_{j} )}{{1}^{2}} )$$

where σ and l are parameters that are determinable in a training.

It may be provided that at least one of weights α₁, α₂, α₃ and/or parameters σ and l is/are determined in the training of model 112 on data set Dₜ.

A Bayesian optimization is carried out in step 208.

In the example, kernel K_{SOT} is used to conduct a search over the space of kernels K, i.e., the search space. Kernel K_{SOT} is used to determine kernel k* of model 112.

This means that a data set Dₜ that is made up of pairs of kernels and selection criteria, i.e., selection criterion g(k_{D}|D), is predefined in a first step. Selection criterion g(k_{D}|D) is, for example, the log evidence or the Bayesian information criterion, or some other criterion that is defined via kernels. In a training, a Gaussian process including kernel K_{SOT} is learned on data set Dₜ. In the example, this involves the training of weights α₁, α₂, α₃ and/or parameters σ and l.

This Gaussian process is used in a second step to compute an acquisition function a(k|Dₜ) for the Bayesian optimization.

Acquisition function a(k|Dₜ) is maximized in a third step with the aid of an evolutionary algorithm. A new kernel k* is determined in this way.

Selection criterion g(k_{D}|D) is computed for this kernel k* in a fourth step, where D is the data set including input variables X and output variables y. In the example, input variables X and output variables y of model 112 are based on input variables X and output variables y of technical system 110. It may also be provided that an output variable of technical system 110 is an input variable of model 112. It may also be provided that an input variable of technical system 110 is an output variable of model 112. Data set D includes mutually assigned input variables and output variables of technical system 110.

Selection criterion g(k_{D}|D) is determined for a kernel from the set of kernels which is selected from the set of kernels as a function of acquisition function a(k|Dₜ).

Acquisition function a(k|Dₜ) is determined as a function of data set Dₜ, which includes pairs of kernels from the set of kernels and the selection criterion.

The pairs of kernels are determined as a function of kernel K_{SOT} over respectively one pair of kernels from the set of kernels, and as a function of data set Dₜ.

Data set Dₜ₊₁ is formed from Dₜ, and the new pair is formed from selected kernel k* and computed selection criterion g(k D ID), in a fifth step.

The first through fifth steps are repeated for T iterations, for example.

In the example, a Gaussian process is used for the prediction yᵢ for variable y, using kernel k* having the highest value of g(k|D).

The evolutionary algorithm from the third step is described below:

1. Generating a random selection of kernels and their trees, and storing this selection in a set M.

2. Evaluating acquisition function a(k|Dₜ) for kernels of set M.

3. Storing the n kernels with the highest acquisition function a(k|Dₜ).

4. Changing the stored kernels and their trees, a random change being made to the trees via the possible operations:

pi S→S+B

S→S×B

B→B′

5. Determining a new set M that includes the previous set and the newly generated kernels.

6. Repeating steps 2 through 5 for L iterations.

7. Outputting the kernel having the highest value of a(k|Dₜ).

The method optionally includes a step 210.

An input variable of model 112 is received or detected in step 210.

The method includes a step 212.

Prediction yᵢ for variable y is determined in step 212, using model 112. Prediction yᵢ predefines, for example, a setpoint behavior of technical system 110, based on kernel k* of model 112. Prediction yᵢ predefines, for example, the setpoint behavior of technical system 110 without an additional input variable.

It may be provided to determine prediction yᵢ for variable y, using model 112, as a function of input variable X. For example, input variable X is mapped onto prediction yᵢ for variable y, using model 112.

The method includes a step 214.

Prediction yᵢ for variable y is output in step 214.

What is claimed is:

1. A computer-implemented method for determining a prediction for a variable of a technical system, using a machine learning model, wherein a kernel for the model is selected from a set of kernels as a function of a selection criterion and a first data set, the first data set including mutually assigned input variables and output variables of the technical system, the selection criterion being determined for the kernel that is selected from the set of kernels as a function of an acquisition function, the acquisition function being determined as a function of a second data set that includes pairs of kernels from the set of kernels and a selection criterion, the pairs of kernels, as a function of a kernel, being determined over respectively a pair of kernels from the set of kernels and as a function of the second data set, the method comprising the following steps:
providing a representation of a first kernel and a representation of a second kernel from the set of kernels, the representation of the first kernel including at least one symbol that characterizes a kernel, the representation of the second kernel including at least one symbol that characterizes a kernel;
determining a distance between the first kernel and the second kernel as a function of a difference between a number of symbols that characterize a predefined kernel in the representation of the first kernel, and a number of symbols that characterize the predefined kernel in the representation of the second kernel, or as a function of a difference between in relative frequencies of the symbols, a kernel being determined over the first and second kernels for determining the kernel for the model, as a function of the distance; and
determining the prediction for the variable using the model, wherein the variable is a position, or a speed, or an acceleration.

2. The method as recited in claim 1, wherein the representation of the first kernel includes at least one symbol that characterizes an operator via which two kernels are combinable, the representation of the first kernel including at least one sequence of symbols that characterizes an application of at least one operator to a kernel, the representation of the second kernel including at least one symbol that characterizes an operator via which two kernels are combinable, the representation of the second kernel including at least one sequence of symbols that characterizes an application of at least one operator to a kernel, the distance being determined as a function of a difference between a number of sequences in the first representation that include a symbol for the predefined kernel, and a number of sequences in the second representation that include a symbol for the predefined kernel, or as a function of a difference between relative frequencies of the sequences.

3. The method as recited in claim 1, wherein the representation of the first kernel includes at least one symbol that characterizes an operator via which two kernels are combinable, the representation of the first kernel including at least one sequence of symbols that characterizes an application of at least one operator to at least two kernels, the representation of the second kernel including at least one symbol that characterizes an operator via which two kernels are combinable, the representation of the second kernel including at least one sequence of symbols that characterizes an application of at least one operator to at least two kernels, the distance being determined as a function of a difference between a number of sequences in the first representation that include a symbol for the predefined kernel and at least one further kernel, and a number of sequences in the second representation that include a symbol for the predefined kernel and at least one further kernel, or as a function of a difference between relative frequencies of the sequences.

4. The method as recited in claim 2, wherein a weight is determined for at least one of the differences, the distance being determined as a function of a sum in which the at least one difference is weighted with the weight.

5. The method as recited in claim 4, wherein the weight is determined in a training of the model on at least one of the data sets.

6. The method as recited in claim 1, wherein the first kernel includes parameters, values for the parameters that meet a predefined criterion being determined as a function of at least one of the first and second data sets.

7. The method as recited in claim 1, wherein the prediction for the variable is output.

8. The method as recited in claim 1, wherein an input variable of the model is received or detected, the prediction for the variable being determined as a function of the input variable, using the model.

9. A device for determining a variable of a technical system, using a machine learning model, the device comprising:
at least one processor; and
at least one non-transitory memory configured to store instructions for determining a prediction for a variable of a technical system, using a machine learning model, wherein a kernel for the model is selected from a set of kernels as a function of a selection criterion and a first data set, the first data set including mutually assigned input variables and output variables of the technical system, the selection criterion being determined for the kernel that is selected from the set of kernels as a function of an acquisition function, the acquisition function being determined as a function of a second data set that includes pairs of kernels from the set of kernels and a selection criterion, the pairs of kernels, as a function of a kernel, being determined over respectively a pair of kernels from the set of kernels and as a function of the second data set, the instruction, when executed by the at least one processor, causing the at least one processor to perform the following steps:
providing a representation of a first kernel and a representation of a second kernel from the set of kernels, the representation of the first kernel including at least one symbol that characterizes a kernel, the representation of the second kernel including at least one symbol that characterizes a kernel,
determining a distance between the first kernel and the second kernel as a function of a difference between a number of symbols that characterize a predefined kernel in the representation of the first kernel, and a number of symbols that characterize the predefined kernel in the representation of the second kernel, or as a function of a difference between in relative frequencies of the symbols, a kernel being determined over the first and second kernels for determining the kernel for the model, as a function of the distance, and
determining the prediction for the variable using the model, wherein the variable is a position, or a speed, or an acceleration.

10. The device as recited in claim 9, further comprising:
an interface configured to output the variable.

11. The device as recited in claim 9, further comprising:
an interface configured to receive or detect an input variable for the model.

12. A non-transitory computer-readable medium on which is stored a computer program including instructions for determining a prediction for a variable of a technical system, using a machine learning model, wherein a kernel for the model is selected from a set of kernels as a function of a selection criterion and a first data set, the first data set including mutually assigned input variables and output variables of the technical system, the selection criterion being determined for the kernel that is selected from the set of kernels as a function of an acquisition function, the acquisition function being determined as a function of a second data set that includes pairs of kernels from the set of kernels and a selection criterion, the pairs of kernels, as a function of a kernel, being determined over respectively a pair of kernels from the set of kernels and as a function of the second data set, the instruction, when executed by a computer, causing the computer to perform the following steps:
providing a representation of a first kernel and a representation of a second kernel from the set of kernels, the representation of the first kernel including at least one symbol that characterizes a kernel, the representation of the second kernel including at least one symbol that characterizes a kernel,
determining a distance between the first kernel and the second kernel as a function of a difference between a number of symbols that characterize a predefined kernel in the representation of the first kernel, and a number of symbols that characterize the predefined kernel in the representation of the second kernel, or as a function of a difference between in relative frequencies of the symbols, a kernel being determined over the first and second kernels for determining the kernel for the model, as a function of the distance, and
determining the prediction for the variable using the model, wherein the variable is a position, or a speed, or an acceleration.
